(19) United States
(12) Patent Application Publication
(10) Pub. No.: US 2023/0139085 A1
(43) Pub. Date: May 4, 2023

(54) PROCESSING REFERENCE DATA FOR WAFER INSPECTION

(71) Applicant: ASML Netherlands B.V., Veldhoven (NL)

(72) Inventors: Shengcheng JIN, San Jose, CA (US); Haili ZHANG, San Jose, CA (US); Zhichao CHEN, San Jose, CA (US)

(73) Assignee: ASML Netherlands B.V., Veldhoven (NL)

(21) Appl. No.: 17/918,087

(22) PCT Filed: Apr. 6, 2021
(86) PCT No.: PCT/EP2021/058831

§ 371 Date: Oct. 10, 2022

Related U.S. Application Data
(60) Provisional application No. 63/008,178, filed on Apr. 10, 2020.

(51) Int. Cl. G06T 7/00; G01N 23/2251; G03F 7/20

(52) U.S. Cl. CPC G06T 7/001; G01N 23/2251; G06T 7/0006; G03F 7/7065; G03F 7/70625; G01N 2223/07; G01N 2223/401; G01N 2223/418; G06T 2207/30148; G06T 2207/10061

(57) ABSTRACT

An improved apparatus and method for facilitating inspection of a wafer are disclosed. An improved method for facilitating inspection of a wafer comprises identifying a plurality of repeating patterns from reference image data associated with a layout design of the wafer. The method also comprises determining a pattern feature of one of the identified plurality of repeating patterns based on a change of a first characteristic of the reference image data. The method further comprises causing a first area of the wafer corresponding to the determined pattern feature to be evaluated.

### CROSS-REFERENCE TO RELATED APPLICATIONS

This application claims priority of U.S. application 63/008,178 which was filed on Apr. 10, 2020, and which is incorporated herein in its entirety by reference.

### TECHNICAL FIELD

The embodiments provided herein relate to a system and a method for processing reference data of integrated circuit layout for facilitating wafer inspection.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important.

A charged particle (e.g., electron) beam microscope, such as a scanning electron microscope (SEM) or a transmission electron microscope (TEM) can serve as a practicable tool for inspecting IC components. Critical dimensions of patterns or structures measured from SEM or TEM image can be used to detect defects of manufactured ICs. For example, shifts between patterns or edge placement variations can be helpful in controlling manufacturing processes as well as in determining defects.

### SUMMARY

The embodiments provided herein disclose a particle beam inspection apparatus, and more particularly, an inspection apparatus using a plurality of charged particle beams.

In some embodiments, a method for facilitating inspection of a wafer comprises identifying a plurality of repeating patterns from reference image data associated with a layout design of the wafer. The method also comprises determining a pattern feature of one of the identified plurality of repeating patterns based on a change of a first characteristic of the reference image data.

The method further comprises causing a first area of the wafer corresponding to the determined pattern feature to be evaluated.

In some embodiments, an apparatus comprises a memory storing a set of instructions and at least one processor configured to execute the set of instructions to cause the apparatus to perform identifying a plurality of repeating patterns from reference image data associated with a layout design of the wafer. The at least one processor is also configured to execute the set of instructions to cause the apparatus to further perform determining a pattern feature of one of the identified plurality of repeating patterns based on a change of a first characteristic of the reference image data. The at least one processor is also configured to execute the set of instructions to cause the apparatus to further perform causing a first area of the wafer corresponding to the determined pattern feature to be evaluated.

In some embodiments, a non-transitory computer readable medium that stores a set of instructions that is executable by at least one processor of a computing device to cause the computing device to perform a method for facilitating inspection of a wafer. The method comprises identifying a plurality of repeating patterns from reference image data associated with a layout design of the wafer. The method also comprises determining a pattern feature of one of the identified plurality of repeating patterns based on a change of a first characteristic of the reference image data. The method further comprises causing a first area of the wafer corresponding to the determined pattern feature to be evaluated.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a schematic diagram illustrating an example electron beam inspection (EBI) system, consistent with some embodiments of the present disclosure.

FIG. 2 is a schematic diagram illustrating an example electron beam tool that can be a part of the electron beam inspection system of FIG. 1, consistent with some embodiments of the present disclosure.

FIG. 3 is a block diagram of an example apparatus associated with wafer inspection based on reference data analysis, consistent with some embodiments of the present disclosure.

FIG. 4A illustrates examples of a plurality of repeating patterns included in reference data, in accordance with some embodiments of the present disclosure.

FIG. 4B illustrates examples of pattern features of a repeating pattern, in accordance with some embodiments of the present disclosure.

FIG. 5A illustrates examples of cell features including a non-edge area of a repeating pattern, in accordance with some embodiments of the present disclosure.

FIG. 5B illustrates examples of cell features including cell edges of a repeating pattern, in accordance with some embodiments of the present disclosure.

FIG. 6 illustrates examples of classifications of cell defects, in accordance with some embodiments of the present disclosure.

FIG. 7 is a process flowchart representing an example method for analyzing reference data, consistent with some embodiments of the present disclosure.

FIG. 8 is a process flowchart representing an example method for inspecting a wafer, consistent with some embodiments of the present disclosure.

FIG. 9 is a process flowchart representing an example method for evaluating inspection image data, consistent with some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

Critical dimensions of patterns/structures measured from a SEM image is useful for identifying defects. For example, shifts between patterns or edge placement variations, which are determined based on measured critical dimensions, can be used to identify defects of manufactured chips and to control the manufacturing processes thereof. Such critical dimensions of patterns can be obtained from contour information of patterns on a SEM image.

During the wafer inspection process, areas of interest on the wafer (i.e., care areas) may be determined. Care areas may have different shapes, such as polygons, squares, or any other regular or irregular shapes that are suitable for inspection. While various systems and processes can be used to identify care areas on the wafer, many face challenges. For example, certain areas on the wafer, such as cell or array edges, may be difficult to locate accurately due to the massive number of features on an integrated circuit (IC), and the complexity of analyzing the massive data of the IC and of the SEM images of the IC. Areas of interest are often so difficult to automatically identify that the areas of interest may be manually identified for inspection. However, manual identification of care areas often reduces the throughput of the inspection system and is error prone.

In the present disclosure, reference data (also referred to as reference image data, design data, standard data, layout data), such as graphic database system (GDS) data files, can be processed to recognize patterns with certain characteristic(s), such as patterns with repeating structures (e.g., array cells). The processed reference data can also be used to identify a feature of a pattern (e.g., an edge of a cell or array) based on a change of a characteristic in the pattern (e.g., density, pitch, shape, etc.). The processed reference data can then be used to evaluate one or more areas on a wafer during a wafer inspection process. For example, a charged-particle beam inspection system, such as a SEM, can focus on areas on the wafer corresponding to the identified patterns and features in the processed image data for inspection. In another example, inspection image data obtained from the charged-beam inspection system is evaluated based on the identified patterns and features in the processed image data. Accordingly, wafer inspection can be performed with improved efficiency and accuracy.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and

B, or A and C, or B and C, or A and B and C.

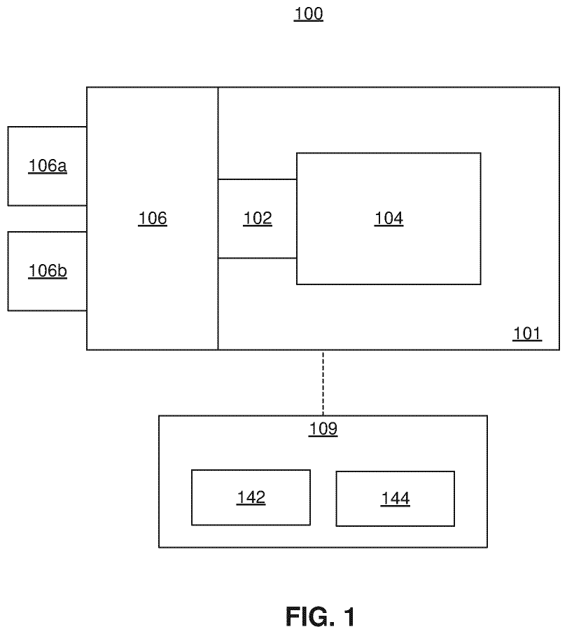

FIG. 1 illustrates an exemplary electron beam inspection (EBI) system 100 consistent with some embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system. It is appreciated that the system and method discussed herein can apply to both single-beam system and multi-beam system.

A controller 109 is electronically connected to electron beam tool 104. Controller 109 may be a computer configured to execute various controls of EBI system 100. Controller 109 may also include processing circuitry configured to execute various signal and image processing functions. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors 142. A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories 144. A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

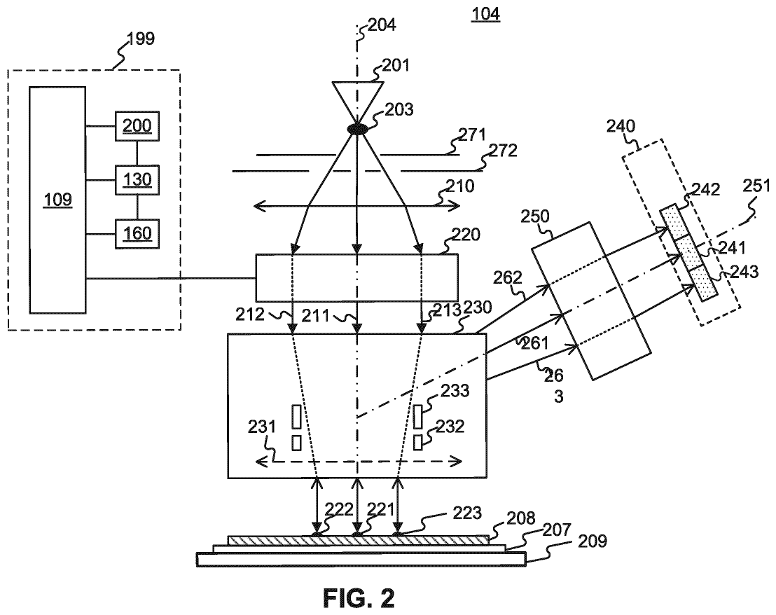

Reference is now made to FIG. 2, which is a schematic diagram illustrating an exemplary electron beam tool 104 including a multi-beam inspection tool that is part of the EBI system 100 of FIG. 1, consistent with some embodiments of the present disclosure. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a wafer 208 to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiment, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2 shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to control operations of one or more components of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principle plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto wafer 208 for inspection and may form, in the current embodiments, three probe spots 221, 222, and 223 on the surface of wafer 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of wafer 208. In response to incidence of primary beamlets 211, 212, and 213 or probe spots 221, 222, and 223 on wafer 208, electrons emerge from wafer 208 and generate three secondary electron beams 261, 262, and 263. Each of secondary electron beams 261, 262, and 263 typically comprise secondary electrons (having electron energy ≤50 eV) and backscattered electrons (having electron energy between 50 eV and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals which are sent to controller 109 or a signal processing system (not shown), e.g., to construct images of the corresponding scanned areas of wafer 208.

In some embodiments, detection elements 241, 242, and 243 detect corresponding secondary electron beams 261, 262, and 263, respectively, and generate corresponding intensity signal outputs (not shown) to an image processing system (e.g., controller 109). In some embodiments, each detection element 241, 242, and 243 may comprise one or more pixels. The intensity signal output of a detection element may be a sum of signals generated by all the pixels within the detection element.

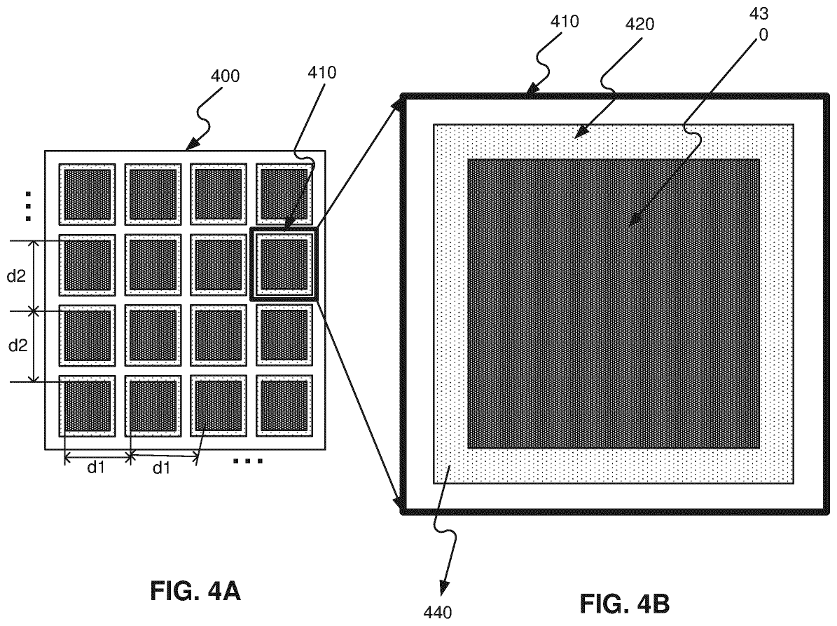

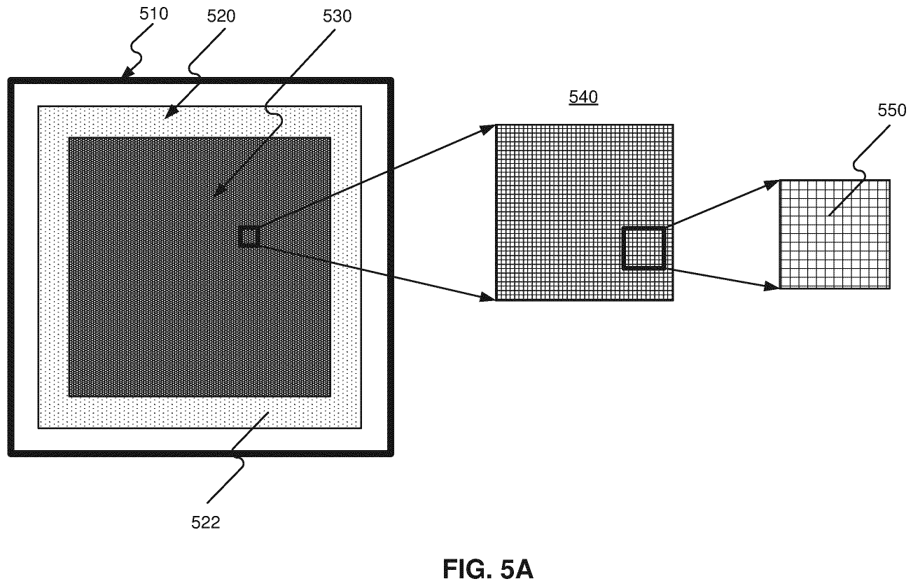

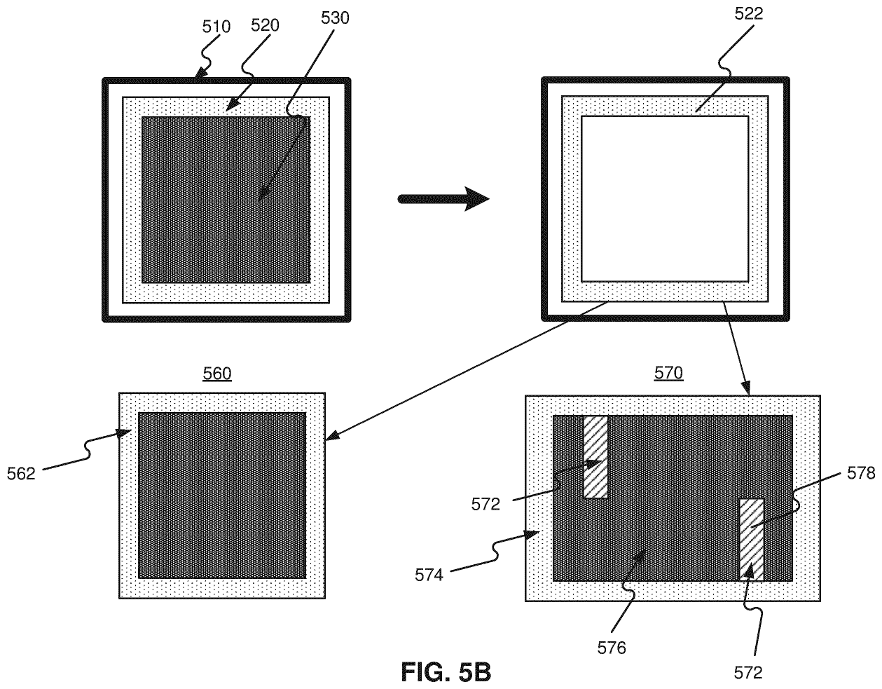

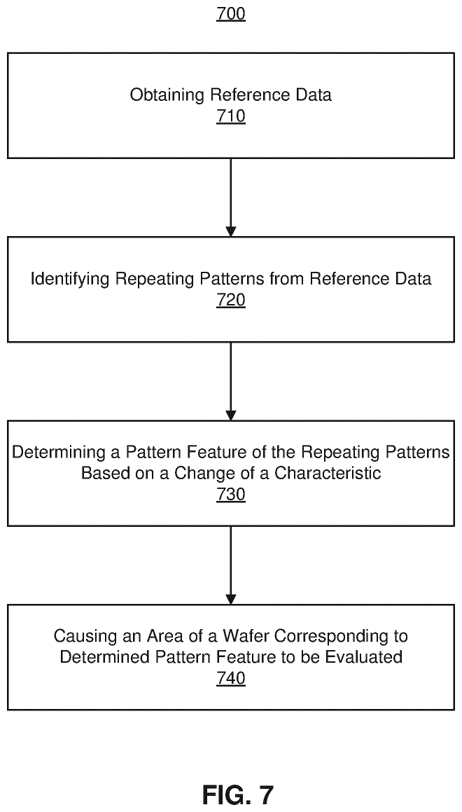

As shown in FIG. 2, a wafer inspection facilitating system 199 (“system 199”) may be provided to communicatively coupled to source conversion unit 220. For example, system 199 may include an inspection image acquirer 200, a storage 130, a reference data acquirer 160 (or “a reference data acquirer 160”), and controller 109 that are communicatively coupled to each other. In some embodiments, inspection image acquirer 200, storage 130, or reference data acquirer 160 may be integrated as a module of controller 109 or system 199, or include a component that can be implemented in controller 109 or system 199. In some embodiments, system 199 or controller 109 may obtain and analyze reference data of IC layout on a wafer as discussed in FIGS. 4A-4B, and 5A-5B. In some embodiments, system 199 or controller 109 may control an inspection process performed by a charged particle multi-beam system (e.g., system 104) based on the processed reference data as discussed in FIGS. 7-9.

Inspection image acquirer 200 may comprise one or more processors. For example, inspection image acquirer 200 may comprise a computer, server, mainframe host, terminals, personal computer, any kind of mobile computing devices, and the like, or a combination thereof. Inspection image acquirer 200 may be communicatively coupled to electron detection device 240 of apparatus 104 through a medium such as an electrical conductor, optical fiber cable, portable storage media, IR, Bluetooth, internet, wireless network, wireless radio, among others, or a combination thereof. Inspection image acquirer 200 may receive a signal from electron detection device 240 and may construct an image. Inspection image acquirer 200 may thus acquire images of wafer 208. Inspection image acquirer 200 may also perform various post-processing functions, such as generating contours, superimposing indicators on an acquired image, and the like. Inspection image acquirer 200 may be configured to perform adjustments of brightness and contrast, etc. of acquired images.

In some embodiments, image acquirer 200 may acquire image data of a wafer based on an imaging signal received from electron detection device 240. An imaging signal may correspond to a scanning operation for conducting charged particle imaging. Acquired image data may correspond to a single image comprising one or more areas that may contain various features (e.g., repeating cell patterns or cell edges as discussed herein) of wafer 208. Acquired image data may be stored in storage 130. The single image may be an original image that may be divided into a plurality of regions. Each of the regions may comprise one imaging area containing a pattern or a feature of wafer 208. The acquired image data may correspond to multiple images of one or more areas of wafer 208 sampled multiple times over a time sequence. The multiple images may be stored in storage 130. In some embodiments, controller 109 may be configured to perform image processing steps as discussed herein to inspection image data associated with the multiple images of one or more areas of wafer 208.

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of wafer 208, and thereby can be used to reveal any defects that may exist in the wafer.

Reference data acquirer 160 may comprise one or more processors. For example, reference data acquirer 160 may comprise a computer, server, mainframe host, terminals, personal computer, any kind of mobile computing devices, and the like, or a combination thereof. Reference data acquirer 160 may be communicatively coupled to storage 130 or other types of internal or external storage (e.g., design database) configured to store reference data used for design and inspection of integrated circuit layout on a wafer. Reference data acquirer 160 may acquirer reference data through a medium such as an electrical conductor, optical fiber cable, portable storage media, IR, Bluetooth, internet, wireless network, wireless radio, among others, or a combination thereof. Reference data may be associated with design of IC layout on a wafer. Reference data (e.g., design data) may be obtained through software simulation, or geometric design and Boolean operations. In some embodiments, reference data may be stored in a data structure, such as a GDS data file or in any suitable data format.

In some embodiments, controller 109 may analyze the reference data acquired by reference data acquirer 160. For example, as discussed in the present disclosure, controller 109 may process the GDS data files to identify repeating patterns corresponding to cell arrays and edges of the cells respectively. Based on the processed GDS data files, controller 109 may also generate control signals to control operations of source conversion unit 220 or other components of electron beam tool 104 to inspect certain areas of wafer 208 using predetermined parameters. For example, the control signals generated by controller 109 may be used to control primary beamlets 211, 212, and 213 to scan probe spots 221, 222, and 223 across certain scanning areas on wafer 208, such as regions corresponding to the identified cell arrays or cell edges.

Storage 130 may be a storage medium such as a hard disk, random access memory (RAM), cloud storage, other types of computer readable memory, and the like. Storage 130 may be coupled with inspection image acquirer 200 and may be used for saving scanned raw image data as original images, and post-processed images. Storage 130 may also be coupled with reference data acquirer 160 and used for saving reference data and post-processed reference data.

In some embodiments, controller 109 may control motorized stage 209 to move wafer 208 during inspection of wafer 208. In some embodiments, controller 109 may enable motorized stage 209 to move wafer 208 in a direction continuously at a constant speed. In other embodiments, controller 109 may enable motorized stage 209 to change the speed of the movement of wafer 208 overtime depending on the steps of scanning process.

As show in FIG. 2, controller 109 may be electronically connected to electron beam tool 104. As discussed herein, controller 109 may be a computer configured to execute various controls of electron beam tool 104. In some embodiments, inspection image acquirer 200, reference data acquirer 160, storage 130, and controller 109 may be integrated together as one control unit.

Although FIG. 2 shows that electron beam tool 104 uses three primary electron beams, it is appreciated that electron beam tool 104 may use two or more number of primary electron beams.

The present disclosure does not limit the number of primary electron beams used in electron beam tool 104. Compared with a single charged-particle beam imaging system (“single-beam system”), a multiple charged-particle beam imaging system (“multi-beam system”) may be designed to optimize throughput for different scan modes. Embodiments of this disclosure provide a multi-beam system with the capability of optimizing throughput for different scan modes by using beam arrays with different geometries. adapting to different throughputs and resolution requirements.

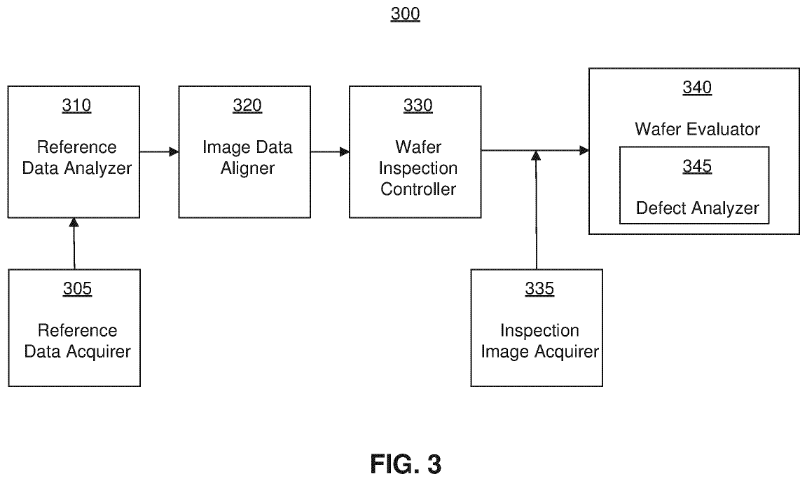

FIG. 3 is a block diagram of an example apparatus 300 associated with wafer inspection based on analysis of reference data, consistent with some embodiments of the present disclosure. In some embodiments, apparatus 300 includes a reference data acquirer 305, a reference data analyzer 310, an image data aligner 320, a wafer inspection controller 330, an inspection image acquirer 335, and a wafer evaluator 340. In some embodiments, wafer evaluator 340 further includes a defect analyzer 345.

It is appreciated that apparatus 300 may include one or more components or modules that are integrated as parts of a charged-particle beam inspection system (e.g., electron beam inspection system 100 of FIG. 1). Apparatus 300 may also include one or more components or modules separate from and communicatively coupled to the charged-particle beam inspection system. Apparatus 300 may comprise one or more processors and memories. For example, apparatus 300 may comprise a computer, server, mainframe host, terminals, personal computer, any kind of mobile computing devices, and the like, or a combination thereof. In some embodiments, apparatus 300 may include one or more components (e.g., software modules) that can be implemented in controller 109 or system 199 as discussed herein.

In some embodiments as shown in FIG. 3, apparatus 300 may include reference data acquirer 305. Reference data acquirer 305 may be configured to obtain reference data (e.g., a part of IC layout design data as shown in FIG. 4A) to be analyzed by reference data analyzer 310 of apparatus 300. In some embodiments, reference data acquirer 305 can be substantially similar to reference data acquirer 160 in FIG. 2. In some embodiments, reference data acquirer 305 may be different from reference data acquirer 160. For example, reference data acquirer 305 may be included or implemented in a computing device separate from the charged-particle beam inspection system.

In some embodiments, the reference data as discussed herein may be in Graphic Database System (GDS) format, Graphic Database System II (GDS II) format, an Open Artwork System Interchange Standard (OASIS) format, a Caltech Intermediate Format (CIF), etc. In some embodiments, reference data may comprise IC design layout on wafer 208 under inspection. The IC design layout may be based on a pattern layout for constructing the wafer. The IC design layout may correspond to one or more photolithography masks or reticles used to transfer features from the photolithography masks or reticles to a wafer. In some embodiments, reference data in GDS or OASIS, among others, may comprise feature information stored in a binary file format representing planar geometric shapes, text, and other information related to wafer design layout.

In some embodiments, the reference data, such as GDS data files, may correspond to a design architecture to be formed on a plurality of hierarchical layers on a wafer. The reference data may be presented in image files and may include characteristics information (e.g., shape, dimension, etc.) for various patterns on different layers that are to be formed on the wafer. For example, reference data may include information associated with various structures, devices, and systems to be fabricated on the wafer, including but not limited to, substrates, doped regions, poly-gate layers, resistance layers, dielectric layers, metal layers, transistors, processors, memories, metal connections, contacts, vias, system-on-chips (SoCs), network-on-chips (NoCs), or any other suitable structures. Reference data may further include IC layout design of memory blocks, logic blocks, interconnects, etc.

In some embodiments, apparatus 300 may include reference data analyzer 310 configured to analyze the reference data obtained from reference data acquirer 305. In some embodiments, reference data analyzer 310 is configured to identify various patterns, such as repeating patterns, in the reference data. For example, reference data analyzer 310 can identify the repeating patterns using any suitable method, such as a repeating pattern identification algorithm, an image recognition algorithm, etc. Reference data analyzer 310 can also identify various pattern features associated with the repeating patterns as discussed with reference to FIGS. 4A-4B and 5A-5B. In some embodiments, reference data analyzer 310 may be configured to perform one or more steps as discussed with reference to FIG. 7. In some embodiments, reference data analyzer 310 may be a part of the charged-particle beam inspection system (e.g., including one or more components or modules that can be implemented in controller 109 or system 199). In some embodiments, reference data analyzer 310 may be included in a computing device separate from and communicatively coupled to the charged-particle beam inspection system.

FIG. 4A is an example of a plurality of repeating patterns 410 in reference data 400 (e.g., a portion of a GDS image), in accordance with some embodiments of the present disclosure. In some examples, repeating patterns 410 may be identified by locating a plurality of feature points in each of patterns 410 that appear to be identical or substantially identical to each other in shape, dimension, material(s), or other suitable factors. In some examples, repeating patterns 410 may be identified by determining that respective distances between corresponding feature points of adjacent repeating patterns 410 are substantially identical. For example, as shown in FIG. 4A, a distance d1 between lower left corners of adjacent patterns may be the same. Similarly, a distance d2 between upper left corners of adjacent patterns may be the same. In some embodiments, the identified repeating patterns 510 may include repeating array cells, such as memory blocks (e.g., static random access memory (SRAM) blocks) on a wafer.

FIG. 4B illustrates examples of various pattern features of a repeating pattern 410, in accordance with some embodiments of the present disclosure. In some embodiments, a pattern feature of a respective repeating pattern 410 may be determined based on a characteristic or a change of a characteristic of reference data associated with repeating patterns 410. In some embodiments, the pattern feature includes a portion of a respective pattern 410, such as a cell edge 420 (e.g., a left edge, a right edge, a top edge, a bottom edge, etc.), a non-edge area 430, a cell corner 440, a cell center, etc. In some embodiments, a cell center is any location within a boundary of a cell or array of cells, e.g., any location within a boundary of an array of memory cells. In some embodiments, the characteristic of the reference data associated with repeating patterns 410 may include a density of features in a unit area, such as a number of patterns, structures, lines, devices, or other suitable features within a respective repeating pattern 410 or a unit area of the repeating pattern 410. In some embodiments, the characteristic of the reference data associated with repeating patterns 410 may include a pitch associated with a repeating pattern 410. In some embodiments, the characteristic of the reference data associated with repeating patterns 410 may include a shape associated with repeating pattern 410.

FIG. 5A illustrates examples of cell features including a non-edge area of a repeating pattern 510, in accordance with some embodiments of the present disclosure. In some embodiments, repeating pattern 510 may be similar to repeating pattern 410 as identified in FIG. 4A as discussed in the present disclosure. As shown in FIG. 5A, repeating pattern 510 includes a first region 530 (e.g., a non-edge area, or an inner portion of the cell or array, or a cell center) with a first feature (e.g., higher density of pattern features) and a second region 520 (e.g., a cell edge) with a second feature (e.g., lower density of pattern features). In some embodiments, pixel information, metadata, or other suitable image information associated with different regions of repeating pattern 510 may be analyzed to determine the features of the different regions respectively.

In some embodiments, a pattern feature may be determined based on a change of a characteristic, such as density, pitch, shape, material, or layer, from one region to another region of repeating pattern 510. In some embodiments, repeating pattern 510 (e.g., a cell area) may be analyzed from an inner portion of the cell area toward an outer portion of the cell area. In some embodiments as shown in FIG. 5A, image information, such as pixel data, associated with a density of feature within first region 530 of repeating pattern 510 (e.g., a cell area) may be analyzed. For example, a portion 540 within first region 530 of repeating pattern 510 may have a first density, a first pitch, a first shape, or a first characteristic 550, among others. In some embodiments, image information associated with second region 520 of repeating pattern 510 may be determined to have a second density, a second pitch, a second shape, or a second characteristic 522, among others. In some embodiments, first characteristic 550 is substantially different from second characteristic 522. For example, as shown in FIG. 5A, first characteristic 550 includes a first density of features in first region 530 that is substantially greater than a second density of features of second characteristic 522 in second region 520. Accordingly, second region 520 is determined to be a cell edge area, and first region 530 is determined to be a non-edge cell area.

FIG. 5B illustrates examples of cell features including cell edges of repeating pattern 510, in accordance with some embodiments of the present disclosure. In some embodiments, repeating pattern 510 may correspond to different types of cells, such as a basic or a simple cell 560 and a more complex cell 570. In some embodiments as shown in FIG. 5B, cell 570 may include a plurality of regions, such as a cell edge 574, a cell center 576, and a third region (e.g., including one or more dummy areas 572) with a third feature. In some embodiments, the third feature of the third region may include a third density (e.g., with a change of density at the boundary between a respective dummy area 572 and cell center 576 and at the boundary between a respective dummy area 572 and cell edge 574), a third pitch (e.g., different from second pitch in cell center 576), a third shape (e.g., different from second shape of cell center 676 and cell edge 674), or any other suitable third characteristic 578.

Referring back to FIG. 3, in some embodiments, apparatus 300 may include image data aligner 320. Image data aligner 320 may be configured to identify or locate areas of wafer 208 that correspond to the pattern feature(s) in the reference data. For example, image data aligner 320 may be configured to identify areas on wafer 208 corresponding to cell edges 420 of the reference data for targeted inspection. In some embodiments, image data aligner 320 may be configured to identify areas of wafer 208 corresponding to various regions in repeating patterns 410 of the reference data determined in step 720 (described below with respect to FIG. 7). In some embodiments, image data aligner 320 of apparatus 300 may be included in or separate from the charged-particle beam inspection system as discussed herein. For example, image data aligner 320 may include one or more components that can be implemented in controller 109 or system 199.

In some embodiments as shown in FIG. 3, apparatus 300 may further include wafer inspection controller 330. In some embodiments, wafer inspection controller 330 may be configured to generate instructions for adjusting electron beam tool 104 for inspection of wafer 208. For example, wafer inspection controller 330 may be configured to generate instructions for inspecting regions of wafer 208 corresponding to the pattern feature(s) of the reference data identified by reference data analyzer 310. For example, wafer inspection controller 330 may be configured to generate instructions for adjusting deflection scanning unit 232 to deflect primary beamlets 211, 212, and 213 to scan probe spots 221, 222, and 223 for inspection of surface areas of wafer 208 corresponding to cell edges 420 or non-edge areas 430.

In some embodiments, wafer inspection controller 330 may be configured to generate instructions to cause the charged-particle beam inspection system (e.g., SEM) to scan the first regions of wafer 208 corresponding to non-edge areas 430 of repeating patterns 410 using a first parameter, and scan the second regions of wafer 208 corresponding to cell edges 420 using a second parameter. The first and second parameters may be associated with a scanning speed, a scanning resolution, an accelerating voltage, a magnification, a size of an electron probe, a focusing power of condenser lens, an aperture size, etc. For example, wafer inspection controller 330 may be configured to cause the SEM to scan areas corresponding to cell edges 420 using a higher resolution or a slower speed than for other regions of repeating patterns 410.

In some embodiments, wafer inspection controller 330 may be included in or separate from the charged-particle beam inspection system as discussed herein. In some embodiments, wafer inspection controller 330 may include one or more components that can be implemented in controller 109 or system 199.

In some embodiments, apparatus 300 may further include inspection image acquirer 335 configured to acquire inspection image data for evaluation (e.g., by wafer evaluator 340 to identify or classify defects). In some embodiments, inspection image acquirer 335 may generate the inspection image data based on a detection signal from electron detection device 240 of electron beam tool 104. In some embodiments, inspection image acquirer 335 may obtain the inspection image data generated by image acquirer 200, controller 109, or system 199. In some embodiments, inspection image acquirer 335 may obtain the inspection image data, such as a SEM image of a portion of wafer 208, from a storage device or system (e.g., storage 130 in FIG. 2). In some embodiments, inspection image acquirer 335 may be similar to, or include one or more components that can be part of inspection image acquirer 200. In some embodiments, inspection image acquirer 335 may include one or more components that can be implemented in controller 109 or system 199 in FIG. 2. In some embodiments, inspection image acquirer 335 may be different from inspection image acquirer 200. For example, inspection image acquirer 335 may be included in a computing device separate from the charged-particle beam inspection system.

In some embodiments, wafer evaluator 340 of apparatus 300 may align the inspection image data with corresponding portions of the reference data (e.g., acquired by reference data acquirer 305 and analyzed by reference data analyzer 310 as discussed herein). In some embodiments, the inspection image data associated with inspection results obtained from scanning areas on wafer 208 corresponding to cell edges 420 may be aligned with cell edges 420 in the reference data. In some examples, inspection image data associated with inspection results from scanning areas on wafer 208 corresponding to the non-edge areas 430 may be aligned with non-edge areas 430 in the reference data.

In some embodiments, wafer evaluator 340 may include defect analyzer 345 for identifying and analyzing defects in respective areas based on the inspection image data.

In some embodiments, defect analyzer 345 may also classify the identified defects based on their respective locations, defect type, etc. In some embodiments, defect analyzer 345 may include one or more components that can be implemented in controller 109 or system 199. In some embodiments, defect analyzer 345 may be part of a computing device separate from electron beam tool 104 or system 100.

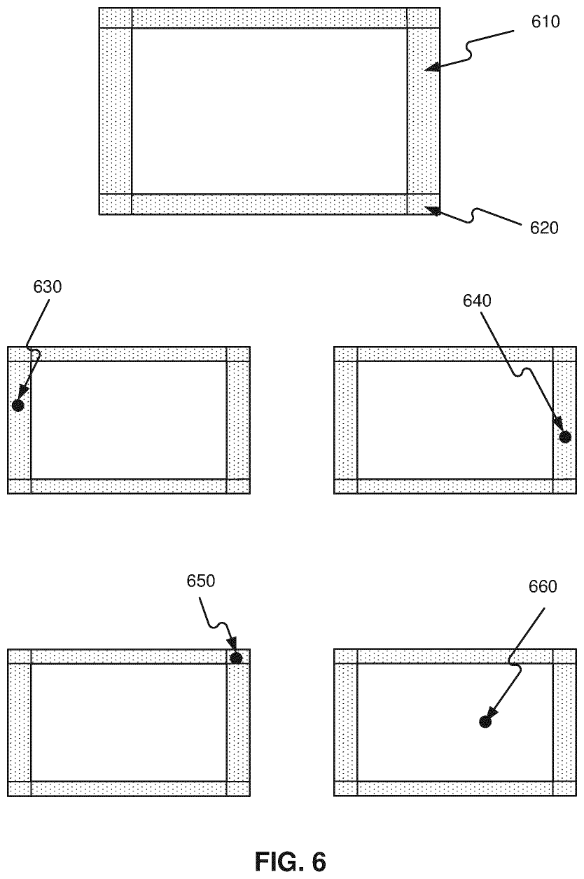

FIG. 6 illustrates examples of classifications of cell defects, in accordance with some embodiments of the present disclosure. In some examples, defects may be identified at different locations, such as on an area corresponding to a cell edge 610 or an area corresponding to a cell corner 620. In some examples, defects may be classified according to their respective locations relative to the repeating patterns (e.g., cells), such as defects on left edges 630, defects on right edges 640, defects on corners 650, defects in non-edge areas 660 (or defects in cell center), and other types of defects.

FIG. 7 is a process flowchart representing an example method 700 for analyzing reference data, consistent with some embodiments of the present disclosure. In some embodiments, one or more steps are performed by one or more components of apparatus 300 in FIG. 3, controller 109 or system 199 in FIG. 2, or system 100 in FIG. 1.

As shown in FIG. 7, in step 710, reference data is obtained. For example, the reference data may be obtained by reference data acquirer 305 in FIG. 3, or reference data acquirer 160 in FIG.

2. The reference data may be obtained from storage 130 in FIG. 2, or any other suitable IC layout design database. The reference data may be in any suitable data format as discussed herein, such as GDS data files corresponding to an IC design architecture to be formed on a plurality of hierarchical layers on a wafer (e.g., wafer 208).

In step 720, various patterns, such repeating patterns, are identified from the obtained reference data (e.g., via reference data analyzer 310 in FIG. 3 or controller 109 in FIG. 2). In some embodiments, reference data analyzer 310 may analyze the reference data to identify a plurality of repeating patterns (e.g., repeating patterns 410 in FIGS. 4A-4B, repeating patterns 510 in FIGS. 5A-5B). In some examples, the repeating patterns may be identified by locating one or more feature points in each of the repeating patterns that appear to be identical or substantially identical to those in other repeating patterns. The feature points may be compared in shape, dimension, material(s), or other suitable factors. For example, each repeating pattern may include repetitions of identical or substantially similar structures or dimensions (e.g., distance d1 or d2 in FIG. 4A) in the IC design layout. In some embodiments, the repeating patterns may be analyzed and identified from the reference data using any suitable image recognition algorithm, repeating pattern identifying algorithm, or other suitable methods. In some embodiments, the repeating patterns correspond to repeating array cells, such as memory blocks (SRAM blocks) on a wafer.

In step 730, a pattern feature of the repeating patterns identified in step 720 (e.g., repeating patterns 410) is determined (e.g., via reference data analyzer 310 in FIG. 3 or controller 109 in FIG. 2). In some embodiments, the pattern feature may be determined based on a characteristic or a change of a characteristic of the reference data associated with repeating patterns. In some embodiments, the pattern feature includes a portion of a respective repeating pattern, such as a cell edge 420 (e.g., a left edge, a right edge, a top edge, a bottom edge, etc.), a cell corner 440, a non-edge area 430 of a cell (an inner portion of a cell, or a cell center), etc., as shown in FIG. 4B.

In some embodiments, the characteristic (e.g., first characteristic 550, second characteristic 522, or third characteristic 578) of the reference data associated with the repeating patterns (e.g., repeating pattern 510) may include a density of features in a unit area, such as a number of patterns, structures, lines, devices, or other suitable features within a respective repeating pattern. In some embodiments, the characteristic of the reference data associated with repeating patterns may include a pitch, a shape, or any other suitable characteristic associated with the repeating patterns.

In some embodiments, pattern features may be automatically identified in step 730 using any suitable image analyzing algorithm or pattern analyzing algorithm. In some embodiments, different regions of repeating pattern 410, such as cell edge 420 and non-edge area 430, may be automatically identified by reference data analyzer 310 without requiring manual identification, thus increasing the throughput of the system and reducing errors.

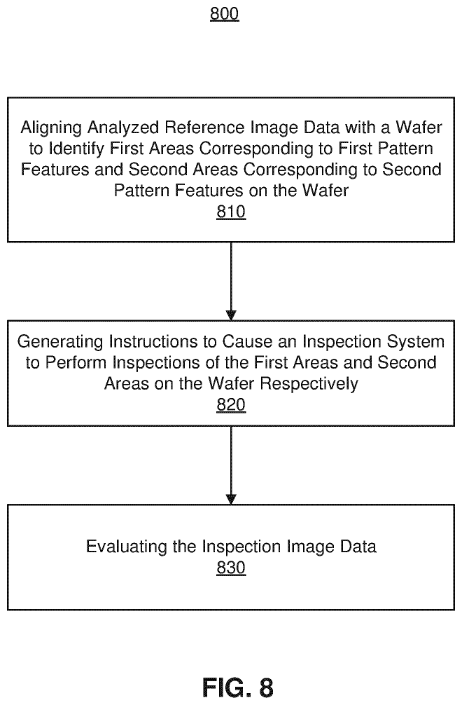

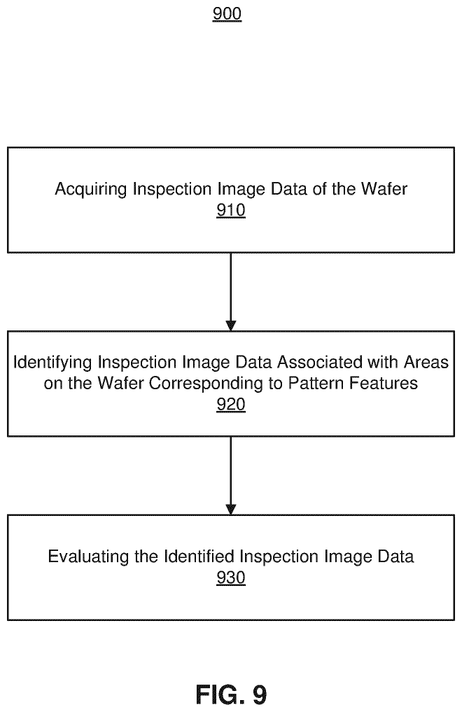

In step 740, an evaluation of an area of wafer (e.g., wafer 208) corresponding to the pattern feature determined in step 730, (e.g., cell edge 420), is performed. In some embodiments, step 740 may be performed by one or more components of apparatus 300 in FIG. 3, such as an image data aligner 320, a wafer inspection controller 330, an inspection image acquirer 335, or a wafer evaluator 340. In some embodiments, step 740 may be performed by one or more components of system 199 in FIG. 2 (e.g., controller 109), or system 100 in FIG. 1. In some embodiments, inspection of defects may be performed on the area of wafer 208 corresponding to the determined pattern feature (e.g., cell edge 420, cell edge 520, cell edge 562, or cell edge 574). In some embodiments, step 740 may be performed in different embodiments, such as method 800 in FIG. 8, or method 900 in FIG. 9 respectively.

FIG. 8 is a process flowchart representing an example method 800 for inspecting a wafer (e.g., wafer 208), consistent with some embodiments of the present disclosure. In some embodiments, one or more steps of method 800 are performed by one or more components of apparatus 300 in FIG. 3 (e.g., image data aligner 320, wafer inspection controller 330, inspection image acquirer 335, or wafer evaluator 340), system 199 in FIG. 2 (e.g., controller 109), or system 100 in FIG. 1.

In step 810, the reference data (e.g., GDS data file) that has been analyzed (e.g., in accordance with steps 720 of method 700) is aligned (e.g., via image data aligner 320) with the wafer (e.g., wafer 208) to identify or locate areas corresponding to various regions of repeating patterns (e.g., repeating patterns 410 or repeating patterns 510 as identified in step 720). Further in step 810, areas corresponding to different pattern features, (e.g., identified in step 720 of method 700) can also be identified. For example, first areas on the wafer (e.g., wafer 208) corresponding to non-edge areas (e.g., non-edge areas 430 of repeating patterns 410) and second areas on the wafer (e.g., wafer 208) corresponding to cell edges (e.g., cell edges 420 of repeating pattern 410) may be identified respectively.

In step 820, instructions are generated to cause the charged-particle beam inspection system as discussed herein (e.g., system 100 or electron beam tool 104) to perform inspections of the identified areas, such as first areas of the wafer corresponding to the non-edge areas (e.g., non-edge areas 430 of FIG. 4B) of the repeating patterns (e.g., repeating patterns 410 of FIGS. 4A-4B) and the second areas of the wafer corresponding to the cell edges (e.g., cell edges 420 of FIG. 4B) respectively.

In some embodiments, step 820 may be performed by wafer inspection controller 330. For example, in step 820, instructions may be generated to adjust the charged-particle beam inspection system (e.g., adjusting deflection scanning unit 232 to deflect primary beamlets 211, 212, and 213 to scan probe spots 221, 222, and 223) to inspect the identified areas, e.g., the first areas or the second areas identified in step 810 on the wafer. In some embodiments, instructions may be further generated to inspect the first areas using a first parameter, and the second areas using a second parameter different from the first parameter. For example, the areas on the wafer corresponding to the cell edges may be scanned using a slower speed or a higher resolution than the areas on the wafer corresponding to the non-edge areas, or vice-versa.

In step 830 in FIG. 8, the inspection image data is acquired and evaluated. In some embodiments, the inspection image data may be acquired (e.g., via inspection image acquire 335) for evaluation (e.g., via wafer evaluator 340). As discussed herein, the wafer evaluator may align the inspection image data with corresponding portions of the reference data. For example, inspection image data of areas on the wafer corresponding to the cell edges may be aligned to the cell edges in the reference data. In some embodiments, the inspection image data may be further analyzed by defect analyzer 345. For example, defects on the areas corresponding to cell edges may be identified, analyzed, or classified (e.g., as shown in FIG. 6).

FIG. 9 is a process flowchart representing an example method 900 for evaluating inspection image data, consistent with some embodiments of the present disclosure. As discussed above in FIG. 8, in method 800, the reference data analyzed according to steps 720 and 730 of method 700 is used for identifying areas on wafer 802 prior to scanning the wafer surface to perform inspections of respective areas. On the other hand, in method 900, the reference data analyzed according to steps 720 and 730 of method 700 is used for analyzing and evaluating the inspection image data after scanning the wafer surface. In some embodiments, one or more steps of method 900 may be performed by one or more components of apparatus 300 in FIG. 3 (e.g., inspection image acquirer 335, or wafer evaluator 340), system 199 in FIG. 2 (e.g., controller 109), or system 100 in FIG. 1.

In step 910, inspection image data from scanning a wafer (e.g., wafer 208) is acquired. In some embodiments, an inspection image acquirer (e.g., inspection image acquirer 335 of apparatus 300 of FIG. 3) may acquire the inspection image data after performing inspection of wafer 208 for evaluation in the following steps. In some embodiments, inspection image acquirer 335 may generate the inspection image data based on a detection signal from electron detection device 240 of electron beam tool 104. In some embodiments, inspection image acquirer 335 may obtain the inspection image data generated by image acquirer 200 or controller 109. In some embodiments, inspection image acquirer 335 may obtain the inspection image data from a storage device or system (e.g., storage 130 in FIG. 2).

In step 920, a set of inspection image data associated with areas on wafer 208 that correspond to the pattern features (e.g., cell edges or non-edge areas as determined in step 730) is identified from the inspection image data obtained in step 910. Step 920 may be performed by wafer evaluator 340 of apparatus 300, or controller 109. In some embodiments, wafer evaluator 340 may align the analyzed reference data (e.g., GDS data) obtained from steps 720 and 730 of method 700 with corresponding portions of the inspection image data (e.g., associated with inspection of a wafer, a die area, or a portion of a die). In some embodiments, in step 920, the set of inspection image data associated with the areas corresponding to identified pattern features in the reference data may be identified, such as inspection image data of areas on the wafer corresponding to cell edges, non-edge areas, or other regions of the reference data.

In step 930, the set of inspection image data identified in step 920 is evaluated (e.g., by wafer evaluator 340). As discussed above, wafer evaluator 340 may align the set of inspection image data with corresponding portions of the reference data. Wafer evaluator 340 may include defect analyzer 345 for identifying and analyzing defects in corresponding areas of the wafer based on the inspection image data. In some embodiments, as shown in FIG. 6, defects may be identified at different locations, such as on an area corresponding to a cell edge (e.g., cell edge 610) or an area corresponding to a cell corner (e.g., cell corner 620). In some examples, defects may be classified according to their respective locations relative to the repeating patterns (e.g., array cells), such as defects on left edges 630, defects on right edges 640, defects on corners 650, defects in non-edge areas 660 (e.g., defects in cell center), and other types of defects.

The embodiments may further be described using the following clauses:

1. A method of facilitating inspection of a wafer, the method comprising:
identifying a plurality of repeating patterns from reference image data associated with a layout design of the wafer;
determining a pattern feature of one of the identified plurality of repeating patterns based on a change of a first characteristic of the reference image data; and
causing a first area of the wafer corresponding to the determined pattern feature to be evaluated.

2. The method of clause 1, wherein the plurality of repeating patterns corresponds to a plurality of array cells on the wafer.

3. The method of clause 2, wherein the plurality of array cells correspond to a plurality of memory cells.

4. The method of any one of clauses 1-3, wherein the first characteristic of the plurality of repeating patterns includes a density of features associated with the repeating patterns.

5. The method of any one of clauses 1-4, wherein the first characteristic of the plurality of repeating patterns includes a pitch associated with the repeating patterns.

6. The method of any one of clauses 1-5, wherein the first characteristic of the plurality of repeating patterns includes a shape associated with the repeating patterns.

7. The method of any one of clauses 1-6, wherein the pattern feature includes an edge of the respective repeating pattern.

8. The method of any one of clauses 1-7, wherein causing the first area of the wafer to be evaluated comprises:
causing to detect one or more defects in the first area corresponding to the determined pattern feature.

9. The method of any one of clauses 1-8, wherein causing the first area of the wafer to be evaluated comprises:
identifying the first area on the wafer corresponding to the determined pattern feature; and
causing an inspection system to inspect the identified first area on the wafer.

10. The method of any one of clauses 1-9, further comprising:
causing the inspection system to inspect the identified first area using a first parameter; and
causing the inspection system to inspect a second area on the wafer using a second parameter.

11. The method of any one of clauses 1-8, wherein causing the first area of the wafer to be evaluated comprises:
obtaining inspection image data of the wafer from an inspection system after performing the inspection of the wafer;
identifying, from the obtained inspection image data of the wafer, a set of inspection image data associated with the first area on the wafer corresponding to the determined pattern feature; and
evaluating the identified set of inspection image data based on the determined pattern feature in the reference image data.

12. The method of any one of clauses 1-11, wherein the inspection of the wafer is performed using a charged-particle beam inspection system.

13. The method of any one of clauses 1-12, wherein the first reference image is in Graphic Database System (GDS) format, Graphic Database System II (GDS II) format, Open Artwork System Interchange Standard (OASIS) format, or Caltech Intermediate Format (CIF).

14. An apparatus for facilitating inspection of a wafer, comprising:
a memory storing a set of instructions; and
at least one processor configured to execute the set of instructions to cause the apparatus to perform:
   identifying a plurality of repeating patterns from reference image data associated with a layout design of the wafer;
   determining a pattern feature of one of the identified plurality of repeating patterns based on a change of a first characteristic of the reference image data; and
   causing a first area of the wafer corresponding to the determined pattern feature to be evaluated.

15. The apparatus of clause 14, wherein the plurality of repeating patterns corresponds to a plurality of array cells on the wafer.

16. The apparatus of clause 15, wherein the plurality of array cells correspond to a plurality of memory cells.

17. The apparatus of any one of clauses 14-16, wherein the first characteristic of the plurality of repeating patterns includes a density of features associated with the repeating patterns.

18. The apparatus of any one of clauses 14-17, wherein the first characteristic of the plurality of repeating patterns includes a pitch associated with the repeating patterns.

19. The apparatus of any one of clauses 14-18, wherein the first characteristic of the plurality of repeating patterns includes a shape associated with the repeating patterns.

20. The apparatus of any one of clauses 14-19, wherein the pattern feature includes an edge of the respective repeating pattern.

21. The apparatus of any one of clauses 14-20, wherein causing the first area of the wafer to be evaluated comprises:
causing to detect one or more defects in the first area corresponding to the determined pattern feature.

22. The apparatus of any one of clauses 14-21, wherein causing the first area of the wafer to be evaluated comprises:
identifying the first area on the wafer corresponding to the determined pattern feature; and
causing an inspection system to inspect the identified first area on the wafer.

23. The apparatus of any one of clauses 14-22, the at least one processor is configured to execute the set of instructions to cause the apparatus to further perform:
causing the inspection system to inspect the identified first area using a first parameter; and
causing the inspection system to inspect a second area on the wafer using a second parameter.

24. The apparatus of any one of clauses 14-21, wherein causing the first area of the wafer to be evaluated comprises:
obtaining inspection image data of the wafer from an inspection system after performing the inspection of the wafer;
identifying, from the obtained inspection image data of the wafer, a set of inspection image data associated with the first area on the wafer corresponding to the determined pattern feature; and
evaluating the identified set of inspection image data based on the determined pattern feature in the reference image data.

25. The apparatus of any one of clauses 14-24, wherein the inspection of the wafer is performed using a charged-particle beam inspection system.

26. The apparatus of any one of clauses 14-25, wherein the apparatus is communicatively coupled to or integrated in a charged particle multi-beam system.

27. The apparatus of any one of clauses 14-26, wherein the first reference image is in Graphic Database System (GDS) format, Graphic Database System II (GDS II) format, Open Artwork System Interchange Standard (OASIS) format, or Caltech Intermediate Format (CIF).

28. A non-transitory computer readable medium that stores a set of instructions that is executable by at least one processor of a computing device to cause the computing device to perform a method for extracting pattern contour information from an inspection image, the method comprising:
identifying a plurality of repeating patterns from reference image data associated with a layout design of the wafer;
determining a pattern feature of one of the identified plurality of repeating patterns based on a change of a first characteristic of the reference image data; and
causing a first area of the wafer corresponding to the determined pattern feature to be evaluated.

29. The computer readable medium of clause 28, wherein the plurality of repeating patterns corresponds to a plurality of array cells on the wafer.

30. The computer readable medium of clause 29, wherein the plurality of array cells correspond to a plurality of memory cells.

31. The computer readable medium of any one of clauses 28-30, wherein the first characteristic of the plurality of repeating patterns includes a density of features associated with the repeating patterns.

32. The computer readable medium of any one of clauses 28-31, wherein the first characteristic of the plurality of repeating patterns includes a pitch associated with the repeating patterns.

33. The computer readable medium of any one of clauses 28-32, wherein the first characteristic of the plurality of repeating patterns includes a shape associated with the repeating patterns.

34. The computer readable medium of any one of clauses 28-33, wherein the pattern feature includes an edge of the respective repeating pattern.

35. The computer readable medium of any one of clauses 28-34, wherein causing the first area of the wafer to be evaluated comprises:
causing to detect one or more defects in the first area corresponding to the determined pattern feature.

36. The computer readable medium of any one of clauses 28-35, wherein causing the first area of the wafer to be evaluated comprises:
identifying the first area on the wafer corresponding to the determined pattern feature; and
causing an inspection system to inspect the identified first area on the wafer.

37. The computer readable medium of any one of clauses 28-36, wherein the set of instructions that is executable by at least one processor of the computing device to cause the computing device to further perform:
causing the inspection system to inspect the identified first area using a first parameter; and
causing the inspection system to inspect a second area on the wafer using a second parameter.

38. The computer readable medium of any one of clauses 28-35, wherein causing the first area of the wafer to be evaluated comprises:
obtaining inspection image data of the wafer from an inspection system after performing the inspection of the wafer;
identifying, from the obtained inspection image data of the wafer, a set of inspection image data associated with the first area on the wafer corresponding to the determined pattern feature; and
evaluating the identified set of inspection image data based on the determined pattern feature in the reference image data.

39. The computer readable medium of any one of clauses 28-38, wherein the inspection of the wafer is performed using a charged-particle beam inspection system.

40. The computer readable medium of any one of clauses 28-39, wherein the first reference image is in Graphic Database System (GDS) format, Graphic Database System II (GDS II) format, Open Artwork System Interchange Standard (OASIS) format, or Caltech Intermediate Format (CIF).

A non-transitory computer readable medium may be provided that stores instructions for a processor of a controller (e.g., controller 109 of FIGS. 1-2) to carry out, among other things, image inspection, image acquisition, stage positioning, beam focusing, electric field adjustment, beam bending, condenser lens adjusting, activating charged-particle source, beam deflecting, and methods 700, 800, and 900. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A method of facilitating inspection of a wafer, the method comprising:
identifying a plurality of repeating patterns from reference image data associated with a layout design of the wafer;
determining a pattern feature of one of the identified plurality of repeating patterns based on a change of a first characteristic of the reference image data; and
causing a first area of the wafer corresponding to the determined pattern feature to be evaluated.

2. An apparatus for facilitating inspection of a wafer, comprising:
a memory storing a set of instructions; and
at least one processor configured to execute the set of instructions to cause the apparatus to perform:
identifying a plurality of repeating patterns from reference image data associated with a layout design of the wafer;
determining a pattern feature of one of the identified plurality of repeating patterns based on a change of a first characteristic of the reference image data; and
causing a first area of the wafer corresponding to the determined pattern feature to be evaluated.

3. The apparatus of claim 2, wherein the plurality of repeating patterns corresponds to a plurality of array cells on the wafer.

4. The apparatus of claim 3, wherein the plurality of array cells correspond to a plurality of memory cells.

5. The apparatus of claim 2, wherein the first characteristic of the plurality of repeating patterns includes a density of features associated with the repeating patterns.

6. The apparatus of claim 2, wherein the first characteristic of the plurality of repeating patterns includes a pitch associated with the repeating patterns.

7. The apparatus of claim 2, wherein the first characteristic of the plurality of repeating patterns includes a shape associated with the repeating patterns.

8. The apparatus of claim 2, wherein the pattern feature includes an edge of the respective repeating pattern.

9. The apparatus of claim 2, wherein causing the first area of the wafer to be evaluated comprises:
causing to detect one or more defects in the first area corresponding to the determined pattern feature.

10. The apparatus of claim 2, wherein causing the first area of the wafer to be evaluated comprises:
identifying the first area on the wafer corresponding to the determined pattern feature; and
causing an inspection system to inspect the identified first area on the wafer.

11. The apparatus of claim 2, the at least one processor is configured to execute the set of instructions to cause the apparatus to further perform:
causing the inspection system to inspect the identified first area using a first parameter; and
causing the inspection system to inspect a second area on the wafer using a second parameter.

12. The apparatus of claim 2, wherein causing the first area of the wafer to be evaluated comprises:
obtaining inspection image data of the wafer from an inspection system after performing the inspection of the wafer;
identifying, from the obtained inspection image data of the wafer, a set of inspection image data associated with the first area on the wafer corresponding to the determined pattern feature; and
evaluating the identified set of inspection image data based on the determined pattern feature in the reference image data.

13. The apparatus of claim 2, wherein the inspection of the wafer is performed using a charged-particle beam inspection system.

14. The apparatus of claim 2, wherein the apparatus is communicatively coupled to or integrated in a charged particle multi-beam system.

15. A non-transitory computer readable medium that stores a set of instructions that is executable by at least one processor of a computing device to cause the computing device to perform a method for extracting pattern contour information from an inspection image, the method comprising:
identifying a plurality of repeating patterns from reference image data associated with a layout design of the wafer;
determining a pattern feature of one of the identified plurality of repeating patterns based on a change of a first characteristic of the reference image data; and
causing a first area of the wafer corresponding to the determined pattern feature to be evaluated.
